(19) United States
(12) Patent Application Publication
(10) Pub. No.: US 2025/0185321 A1
(43) Pub. Date: Jun. 5, 2025

(54) DISCONNECTED GATE DIELECTRIC FOR TRANSISTORS

(71) Applicant: International Business Machines Corporation, Armonk, NY (US)

(72) Inventors: Ruqiang Bao, Niskayuna, NY (US); Effendi Leobandung, Stormville, NY (US)

(21) Appl. No.: 18/529,060

(22) Filed: Dec. 5, 2023

(51) Int. Cl. H01L 29/10; H01L 29/06; H01L 29/417; H01L 29/423; H01L 29/66; H01L 29/775; H01L 29/78; H01L 29/786

(52) U.S. Cl. CPC H10D 62/364; H10D 30/024; H10D 30/43; H10D 30/62; H10D 30/6219; H10D 30/6735; H10D 30/6757; H10D 62/121; H10D 30/014

(57) ABSTRACT

A semiconductor device is provided. The semiconductor device includes a substrate, first and second field effect transistors (FETs) of opposite polarity, the first FET being disposed on a first side of the substrate and including first work function metal (WFM) and the second FET being disposed on a second side of the substrate and including second WFM, a first gate dielectric disposed over at least the first side of the substrate and a second gate dielectric disconnected from the first gate dielectric and disposed over at least the second side of the substrate. The second WFM is aligned with the second gate dielectric and the first WFM extends beyond the first gate dielectric.

### BACKGROUND

This disclosure generally relates to fabrication methods and resulting structures for semiconductor devices. More specifically, this disclosure relates to disconnected gate dielectric for scaled gate-all-around (GAA) transistors.

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### SUMMARY

According to an aspect of the disclosure, a semiconductor device is provided. The semiconductor device includes a substrate, first and second field effect transistors (FETs) of opposite polarity, the first FET being disposed on a first side of the substrate and including first work function metal (WFM) and the second FET being disposed on a second side of the substrate and including second WFM, a first gate dielectric disposed over at least the first side of the substrate and a second gate dielectric disconnected from the first gate dielectric and disposed over at least the second side of the substrate. The second WFM is aligned with the second gate dielectric and the first WFM extends beyond the first gate dielectric. In additional or alternative embodiments, the semiconductor device provides corrects for a metal gate boundary effect and provides for an alternative path for oxygen vacancy diffusion without causing gate dielectric damage.

A semiconductor device is provided. The semiconductor device includes a substrate including a shallow trench isolation (STI), an n-doped field effect transistor (nFET) disposed on a first side of the substrate, a p-doped field effect transistor (pFET) disposed on a second side of the substrate, a first gate dielectric disposed over the first side of the substrate and a first section of the STI and a second gate dielectric disconnected from the first gate dielectric and disposed over the second side of the substrate and a second section of the STI. The pFET includes pFET work function metal (WFM) aligned with the second gate dielectric and the nFET includes nFET WFM extending beyond the first gate dielectric to contact a third section of the STI, which is interposed between the first and second sections of the STI. In additional or alternative embodiments, the semiconductor device provides corrects for a metal gate boundary effect and provides for an alternative path for oxygen vacancy diffusion without causing gate dielectric damage.

A semiconductor device fabrication method with first and second field effect transistor (FET) structures being formed on a substrate comprising a shallow trench isolation (STI) and the second FET structure including second gate dielectric and polysilicon is provided. The semiconductor device fabrication method includes disposing first gate dielectric over the substrate and exposed portions of the STI, the second gate dielectric and the polysilicon, depositing a sacrificial layer over the first gate dielectric, masking a portion of the sacrificial layer, removing unmasked portions of the sacrificial layer and the first gate dielectric, removing at least a portion of a remainder of the sacrificial layer, depositing a first work function metal (WFM) onto a remainder of the first gate dielectric and an exposed section of the STI and replacing the polysilicon with a second WFM. In additional or alternative embodiments, the semiconductor device provides corrects for a metal gate boundary effect and provides for an alternative path for oxygen vacancy diffusion without causing gate dielectric damage.

Additional technical features and benefits are realized through the techniques of this disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments are apparent from the following detailed description taken in conjunction with the accompanying drawings in which:

FIG. 1 is a side view of a semiconductor device according to one or more embodiments;

FIG. 2 is a flow diagram illustrating a method of semiconductor device fabrication in accordance with one or more embodiments;

FIG. 3 is a flow diagram illustrating a method of semiconductor device fabrication in accordance with one or more embodiments;

FIG. 4 is a top-down view of a semiconductor device assembly being fabricated in accordance with one or more embodiments;

FIG. 5 is a side view of an initial structure of a semiconductor device taken along line “Y-Y” of FIG. 4 in accordance with one or more embodiments;

FIG. 6 is a side view of a secondary structure of a semiconductor device taken along line “Y-Y” of FIG. 4 in accordance with one or more embodiments;

FIG. 7 is a side view of a third structure of a semiconductor device taken along line “Y-Y” of FIG. 4 in accordance with one or more embodiments;

FIGS. 8A and 8B are side views of a fourth structure of a semiconductor device taken along line “Y-Y” of FIG. 4 in accordance with one or more embodiments; and

FIG. 9 is a side view of a fifth structure of a semiconductor device taken along line “Y-Y” of FIG. 4 in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a semiconductor device is provided. The semiconductor device includes a substrate, first and second field effect transistors (FETs) of opposite polarity, the first FET being disposed on a first side of the substrate and including first work function metal (WFM) and the second FET being disposed on a second side of the substrate and including second WFM, a first gate dielectric disposed over at least the first side of the substrate and a second gate dielectric disconnected from the first gate dielectric and disposed over at least the second side of the substrate. The second WFM is aligned with the second gate dielectric and the first WFM extends beyond the first gate dielectric. In additional or alternative embodiments, the semiconductor device provides corrects for a metal gate boundary effect and provides for an alternative path for oxygen vacancy diffusion without causing gate dielectric damage.

The first WFM contacts the second WFM in a plane aligned with an edge of the second gate dielectric. In additional or alternative embodiments, the semiconductor device provides corrects for a metal gate boundary effect and provides for an alternative path for oxygen vacancy diffusion without causing gate dielectric damage.

The first and second FETs are nanosheet transistors. In additional or alternative embodiments, the semiconductor device is compatible with complementary-metal-oxide-semiconductor (CMOS) processes.

The first and second FETs are finFETs. In additional or alternative embodiments, the semiconductor device is compatible with complementary-metal-oxide-semiconductor (CMOS) processes.

The first and second FETs are vertical tunnel FETs. In additional or alternative embodiments, the semiconductor device is compatible with complementary-metal-oxide-semiconductor (CMOS) processes.

The first and second gate dielectrics are different materials. In additional or alternative embodiments, the semiconductor device is compatible with complementary-metal-oxide-semiconductor (CMOS) processes.

The first gate dielectric includes one of an interfacial layer and a high-k dielectric and the second gate dielectric includes an interfacial layer and a high-k dielectric. In additional or alternative embodiments, the semiconductor device is compatible with complementary-metal-oxide-semiconductor (CMOS) processes.

A semiconductor device is provided. The semiconductor device includes a substrate including a shallow trench isolation (STI), an n-doped field effect transistor (nFET) disposed on a first side of the substrate, a p-doped field effect transistor (pFET) disposed on a second side of the substrate, a first gate dielectric disposed over the first side of the substrate and a first section of the STI and a second gate dielectric disconnected from the first gate dielectric and disposed over the second side of the substrate and a second section of the STI. The pFET includes pFET work function metal (WFM) aligned with the second gate dielectric and the nFET includes nFET WFM extending beyond the first gate dielectric to contact a third section of the STI, which is interposed between the first and second sections of the STI. In additional or alternative embodiments, the semiconductor device provides corrects for a metal gate boundary effect and provides for an alternative path for oxygen vacancy diffusion without causing gate dielectric damage.

The nFET WFM contacts the pFET WFM in a plane aligned with an edge of the second gate dielectric. In additional or alternative embodiments, the semiconductor device provides corrects for a metal gate boundary effect and provides for an alternative path for oxygen vacancy diffusion without causing gate dielectric damage.

The nFET and the pFET are nanosheet transistors. In additional or alternative embodiments, the semiconductor device is compatible with complementary-metal-oxide-semiconductor (CMOS) processes.

The nFET and the pFET are finFETs. In additional or alternative embodiments, the semiconductor device is compatible with complementary-metal-oxide-semiconductor (CMOS) processes.

The nFET and the pFET are vertical tunnel FETs. In additional or alternative embodiments, the semiconductor device is compatible with complementary-metal-oxide-semiconductor (CMOS) processes.

The first and second gate dielectrics are different materials. In additional or alternative embodiments, the semiconductor device is compatible with complementary-metal-oxide-semiconductor (CMOS) processes.

The first gate dielectric includes one of an interfacial layer and a high-k dielectric and the second gate dielectric comprises an interfacial layer and a high-k dielectric. In additional or alternative embodiments, the semiconductor device is compatible with complementary-metal-oxide-semiconductor (CMOS) processes.

A semiconductor device fabrication method with first and second field effect transistor (FET) structures being formed on a substrate comprising a shallow trench isolation (STI) and the second FET structure including second gate dielectric and polysilicon is provided. The semiconductor device fabrication method includes disposing first gate dielectric over the substrate and exposed portions of the STI, the second gate dielectric and the polysilicon, depositing a sacrificial layer over the first gate dielectric, masking a portion of the sacrificial layer, removing unmasked portions of the sacrificial layer and the first gate dielectric, removing at least a portion of a remainder of the sacrificial layer, depositing a first work function metal (WFM) onto a remainder of the first gate dielectric and an exposed section of the STI and replacing the polysilicon with a second WFM. In additional or alternative embodiments, the semiconductor device provides corrects for a metal gate boundary effect and provides for an alternative path for oxygen vacancy diffusion without causing gate dielectric damage.

The first gate dielectric includes one of an interfacial layer and a high-k dielectric and the second gate dielectric comprises an interfacial layer and a high-k dielectric. In additional or alternative embodiments, the semiconductor device provides corrects for a metal gate boundary effect and provides for an alternative path for oxygen vacancy diffusion without causing gate dielectric damage.

The first WFM contacts the exposed section of the STI and the second WFM in a plane aligned with an edge of the second gate dielectric. In additional or alternative embodiments, the semiconductor device provides corrects for a metal gate boundary effect and provides for an alternative path for oxygen vacancy diffusion without causing gate dielectric damage.

The first and second FET structures include at least one of nanosheet FETs, finFETs and vertical tunnel FETs. In additional or alternative embodiments, the semiconductor device is compatible with complementary-metal-oxide-semiconductor (CMOS) processes.

The masking of the portion of the sacrificial layer includes masking the portion of the sacrificial layer and the first FET structure. In additional or alternative embodiments, the semiconductor device is compatible with complementary-metal-oxide-semiconductor (CMOS) processes.

The removing of the at least the portion of the remainder of the sacrificial layer comprises removing an entirety of the remainder of the sacrificial layer. In additional or alternative embodiments, the semiconductor device is compatible with complementary-metal-oxide-semiconductor (CMOS) processes.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, certain types of transistor structures suffer from a metal gate boundary effect problem. In a GAA field effect transistor (FET), for example, there is a higher oxygen vacancy in a gate dielectric in an n-doped (nFET) side than in a p-doped (pFET) side. This oxygen vacancy therefore tends to diffuse from the nFET side to the pFET side through the gate dielectric and thus negatively affects a pFET threshold voltage. It has been observed however that efforts to correct for the metal gate boundary effect can lead to gate dielectric damage.

Turning now to an overview of the aspects of the disclosure, one or more embodiments of the disclosure address the above-described shortcomings of the prior art by providing a semiconductor device structure that provides for an alternative path for oxygen vacancy diffusion without causing gate dielectric damage.

The above-described aspects of the disclosure address the shortcomings of the prior art by providing for a semiconductor device that includes a substrate and first and second FETs of opposite polarity, the first FET being disposed on a first side of the substrate and including first WFM and the second FET being disposed on a second side of the substrate and including second WFM. The semiconductor device further includes a first gate dielectric disposed over at least the first side of the substrate and a second gate dielectric disconnected from the first gate dielectric and disposed over at least the second side of the substrate. The second WFM is aligned with the second gate dielectric and the first WFM extends beyond the first gate dielectric.

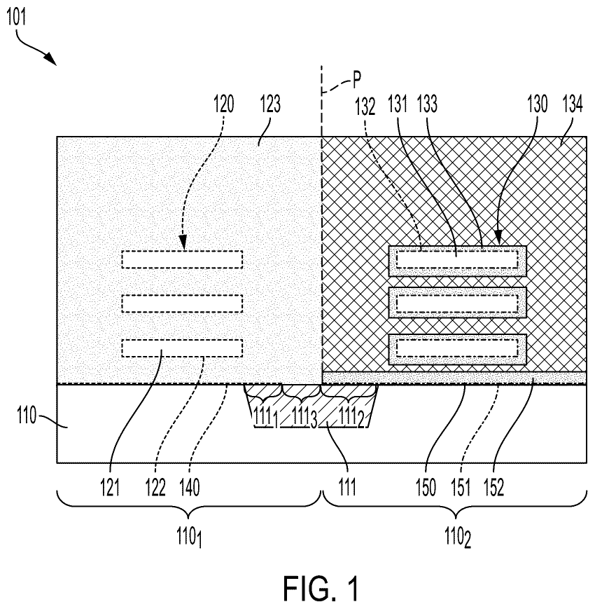

Turning now to a more detailed description of aspects of this disclosure, FIG. 1 depicts a semiconductor device 101. The semiconductor device 101 includes a substrate 110 having a first side 110₁ and a second side 110₂. The substrate 110 includes shallow trench isolation (STI) 111 that partially extends into the first side 110₁ and partially extends into the second side 110₂. The semiconductor device 101 further includes first and second FETs, such as an n-doped FET (nFET) 120 and a p-doped FET (pFET) 130. Hereinafter, the first and second FETs will be referred to as the nFET 120 and the pFET 130. This is being done for clarity and brevity and is not intended to otherwise limit the scope of the application. The nFET 120 is disposed on the first side 110₁ of the substrate 110. The pFET 130 is disposed on the second side 110₂ of the substrate 110.

A first gate dielectric 140 disposed over the first side 110₁ of the substrate 110 and a first section 111₁ of the STI 111. The first gate dielectric 140 can be formed as one of an interfacial layer and a high-k dielectric layer. A second gate dielectric 150 is disconnected from the first gate dielectric 140 and is disposed over the second side 110₂ of the substrate 110 and a second section 111₂ of the STI 111. The second gate dielectric 150 can be formed with a multi-layer structure including an interfacial layer 151 and a high-k dielectric layer 152. In accordance with one or more embodiments a material of the first gate dielectric 140 can differ from materials of the interfacial layer 151 and the high-k dielectric layer 152 of the second gate dielectric 150.

The nFET 120 and the pFET 130 can be provided as one or more of nanosheet transistors, finFETs and vertical tunnel FETs. The following description will relate to the case of the nFET 120 and the pFET 130 being provided as nanosheet transistors. This is being done for purposes of clarity and brevity and is not intended to limit the disclosure or the claims in any way. The pFET 130 thus includes semiconductor channels 131 surrounded by interfacial layers 132 and high-k dielectric layers 133 and pFET work function metal (WFM) 134 that is aligned (i.e., self-aligned) with the second gate dielectric 150. The nFET 120 includes semiconductor channels 121 surrounded by a high-k dielectric layer 122 and nFET WFM 123. The nFET WFM 123 extends over the first gate dielectric 140 and beyond the first gate dielectric 140 to contact a third section 111₃ of the STI 111, which is interposed between the first section 111₁ of the STI 111 and the second section 111₂ of the STI 111.

The nFET WFM 123 thus contacts with the third section 111₂ of the STI 111 and with the pFET WFM 134 in a plane P that is aligned with an interior edge of the second gate dielectric 150. As such, an oxygen vacancy path is provided by the nFET 120 through the nFET WFM 123 and into the third section 111₃ of the STI 111 to reduce a metal gate boundary effect of the semiconductor device 101 without affecting or otherwise damaging the pFET WFM 134.

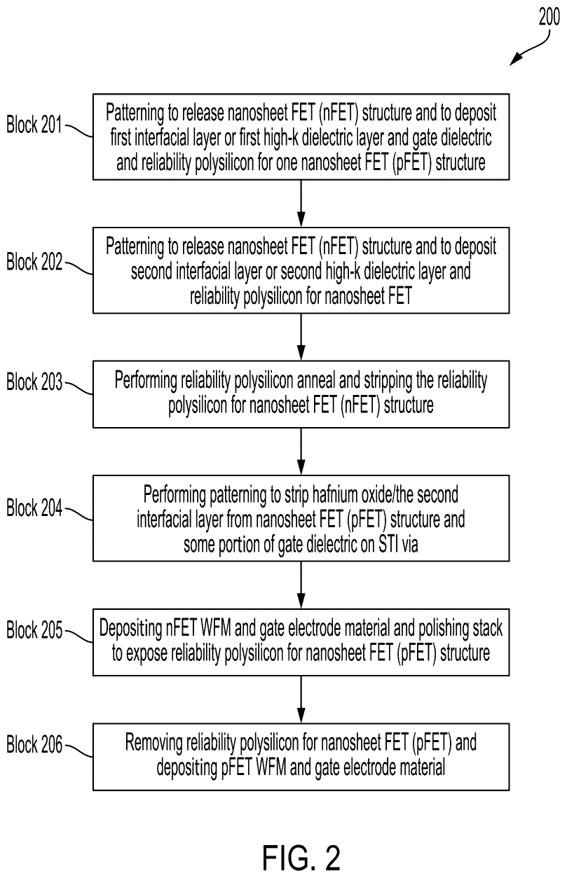

With reference to FIG. 2, a semiconductor device fabrication method 200 is provided. As shown in FIG. 2, the semiconductor device fabrication method 200 includes patterning to release a nanosheet FET (nFET) structure and to deposit a first interfacial layer or a first high-k dielectric layer and gate dielectric and reliability polysilicon for one nanosheet FET (pFET) structure (block 201). As is also shown in FIG. 2, the semiconductor device fabrication method 200 includes patterning to release the nanosheet FET (nFET) structure and to deposit a second interfacial layer or a second high-k dielectric layer and reliability polysilicon for the nanosheet FET (nFET) structure (block 202), performing a reliability polysilicon anneal and stripping the reliability polysilicon for the nanosheet FET (nFET) structure (block 203), performing patterning to strip hafnium oxide/the second interfacial layer from the nanosheet FET (pFET) structure and some portion of gate dielectric on an STI (block 204), depositing nFET WFM and gate electrode material and polishing the stack to expose the reliability polysilicon for the nanosheet FET (pFET) structure (block 205) and removing the reliability polysilicon for the nanosheet FET (pFET) and depositing pFET WFM and gate electrode material (block 206).

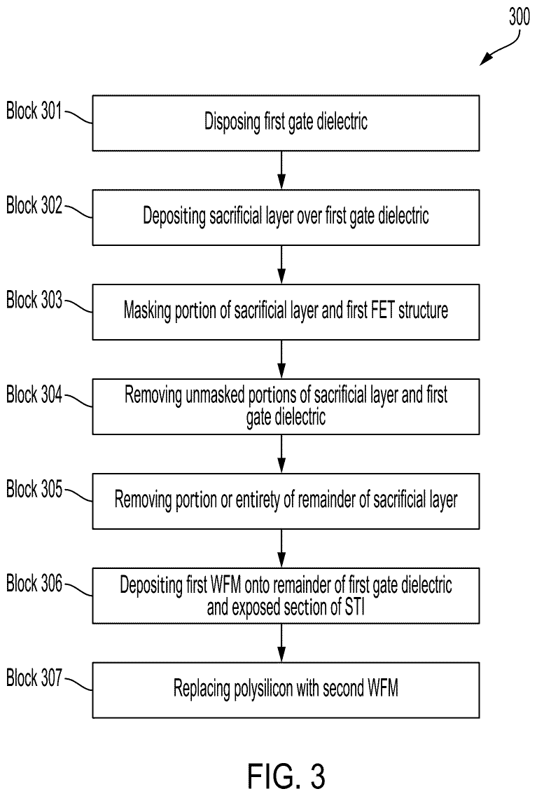

With reference to FIG. 3, a semiconductor device fabrication method 300 with first and second field effect transistor (FET) structures, such as those of the semiconductor device 101 of FIG. 1, being initially formed on a substrate that includes STI and with the second FET structure including second gate dielectric and polysilicon, such as reliability polysilicon. As shown in FIG. 3, the semiconductor device fabrication method 300 includes disposing first gate dielectric over the substrate and exposed portions of the STI, the second gate dielectric and the polysilicon (block 301). As is also shown in FIG. 3, the semiconductor device fabrication method 300 includes depositing a sacrificial layer over the first gate dielectric (block 302), masking a portion of the sacrificial layer and the first FET structure (block 303), removing unmasked portions of the sacrificial layer and the first gate dielectric (block 304), removing at least a portion or an entirety of a remainder of the sacrificial layer (block 305), depositing a first work function metal (WFM) onto a remainder of the first gate dielectric and an exposed section of the STI (block 306) and replacing the polysilicon with a second WFM (block 307).

In accordance with one or more embodiments, the first gate dielectric can include one of an interfacial layer and a high-k dielectric and the second gate dielectric can include an interfacial layer and a high-k dielectric and the first and second FET structures can include at least one of nanosheet FETs, finFETs and vertical tunnel FETs. In any case, the first WFM contacts the exposed section of the STI and the second WFM in a plane aligned with an edge of the second gate dielectric. As such, an oxygen vacancy path is provided by the nFET through the first WFM and into the STI to reduce a metal gate boundary effect of the semiconductor device without affecting or otherwise damaging the second WFM.

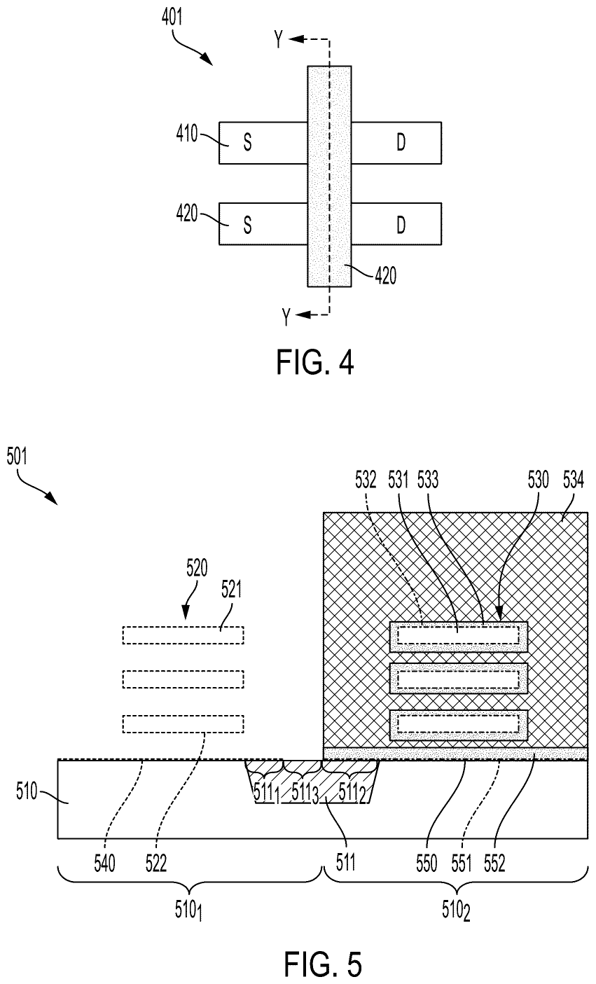

Various stages of the semiconductor device fabrication method 200 of FIG. 2 and the semiconductor device fabrication method 300 of FIG. 3 will now be described with reference to FIG. 4, with additional reference to FIGS. 5-9 and with reference back to FIG. 1.

FIG. 4 depicts a top-down view of a semiconductor device assembly 401 that is being fabricated. The semiconductor device assembly 401 includes an nFET active regions 410 with source/drain (S/D) regions and a pFET active region 420 with S/D regions and a gate 430 extending across the nFET active region 410 and the pFET active region 420. For reference, FIGS. 5-9 and FIG. 1 are taken along the view defined by the line “Y-Y” of FIG. 4.

As shown in FIG. 5, an initial structure 501 of a semiconductor device being fabricated is provided. The initial structure 501 includes a substrate 510 having a first side 510₁ and a second side 510₂. The substrate 510 includes shallow trench isolation (STI) 511 that partially extends into the first side 510₁ and partially extends into the second side 510₂. The initial structure 501 further includes an n-doped FET (nFET) 520 and a p-doped FET (pFET) 530. The nFET 520 is disposed on the first side 510₁ of the substrate 510. The pFET 530 is disposed on the second side 510₂ of the substrate 510.

A first gate dielectric 540 disposed over the first side 510₁ of the substrate 510 and a first section 511₁ of the STI 511 and a third section 511₂ of the STI 511. The first gate dielectric 540 can be formed of hafnium oxide and/or other similar materials and can be formed as one of an interfacial layer and a high-k dielectric layer. A second gate dielectric 550 is disposed over the second side 510₂ of the substrate 510 and a second section 511₂ of the STI 511. The second gate dielectric 550 can be formed with a multi-layer structure including an interfacial layer 551 and a high-k dielectric layer 552. In accordance with one or more embodiments a material of the first gate dielectric 540 can differ from materials of the interfacial layer 551 and the high-k dielectric layer 552 of the second gate dielectric 550.

The nFET 520 and the pFET 530 can be provided as one or more of nanosheet transistors, finFETs and vertical tunnel FETs. The following description will relate to the case of the nFET 520 and the pFET 530 being provided as nanosheet transistors. This is being done for purposes of clarity and brevity and is not intended to limit the disclosure or the claims in any way. The pFET 530 thus includes semiconductor channels 531 surrounded by interfacial layers 532 and high-k dielectric layers 533 and reliability polysilicon 534 that is aligned (i.e., self-aligned) with the second gate dielectric 550. The nFET 520 includes semiconductor channels 521 surrounded by a high-k dielectric layer 522.

The first gate dielectric 540 extends vertically along an interior edge of the second gate dielectric 550 and along an interior edge of the reliability polysilicon 534 and extends over the reliability polysilicon 534.

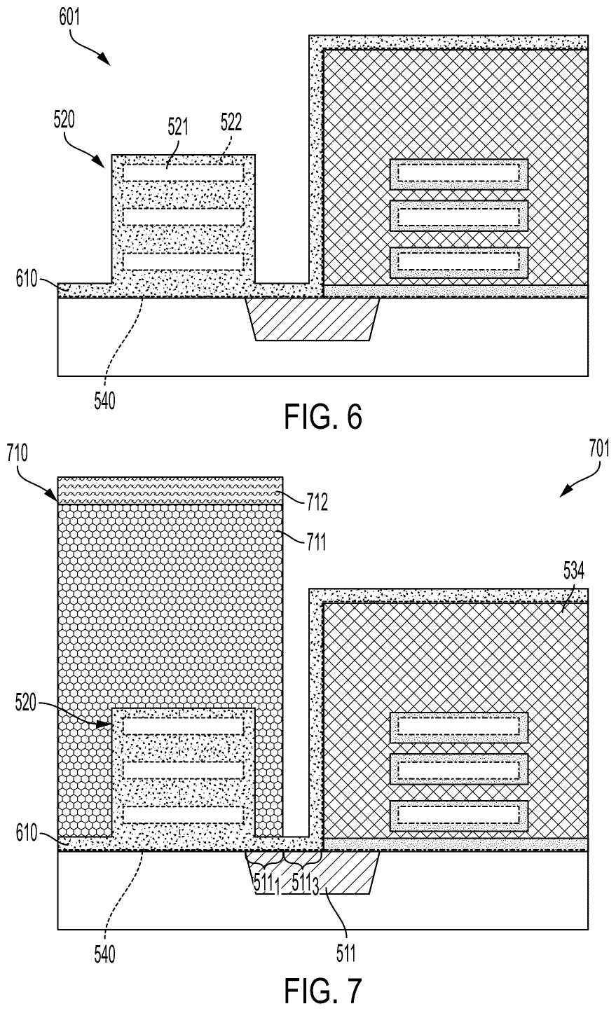

As shown in FIG. 6, a secondary structure 601 of a semiconductor device being fabricated is provided following deposition of a sacrificial layer 610 executed with respect to the initial structure 501 of FIG. 5. The sacrificial layer 610 extends over the first gate dielectric 540 and surrounds the semiconductor channels 521 and the high-k dielectric layer 522 of the nFET 520. The sacrificial layer 610 can include titanium nitride and/or other similar materials.

As shown in FIG. 7, a third structure 701 of a semiconductor device being fabricated is provided following formation of a blocking mask 710 executed with respect to the secondary structure 601 of FIG. 6. The mask 710 can have multiple layers including a first dielectric layer 711 and a second hard mask layer 712 disposed over the first dielectric layer 711. The mask 710 surrounds the nFET 520 and is disposed over a portion of the first gate dielectric 540 (and a corresponding portion of the sacrificial layer 610) that is disposed over the first section 511₁ of the STI 511. The portion of the first gate dielectric 540 (and a corresponding portion of the sacrificial layer 610) that is disposed over the third section 511₃ of the STI 511 as well as the portion of the first gate dielectric 540 that extends vertically along the interior edge of the second gate dielectric 550 and along the interior edge of the reliability polysilicon 534 and that extends over the reliability polysilicon 534 is exposed by the mask 710.

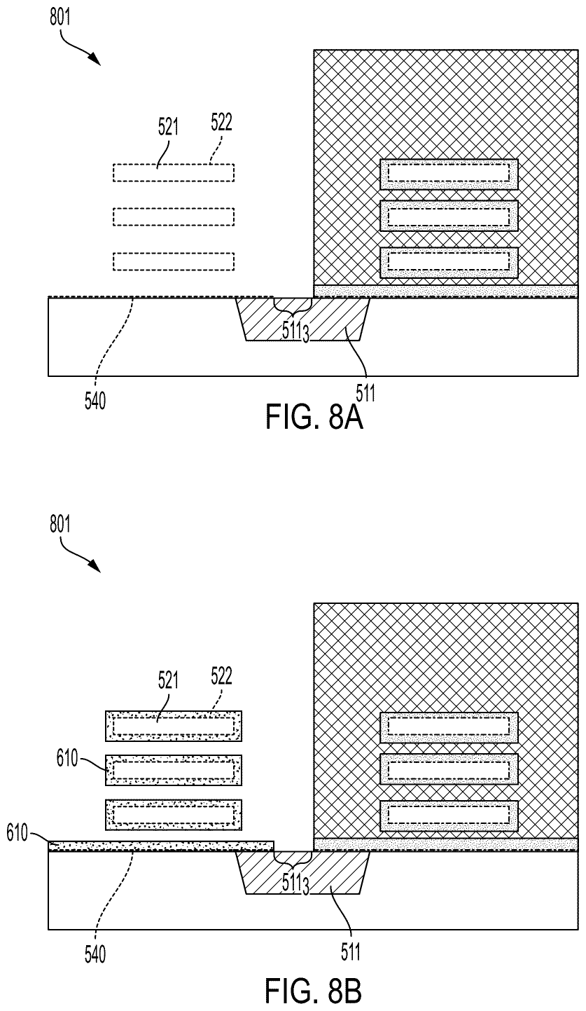

As shown in FIGS. 8A and 8B, a fourth structure 801 of a semiconductor device being fabricated is provided following removals of the second hard mask layer 712, removals of the exposed portions of the sacrificial layer 610 and the first gate dielectric 540, removal of the mask 710 and removal of an entirety of the sacrificial layer 610 (see FIG. 8A) or a portion of the sacrificial layer 610 (see FIG. 8B) executed with respect to the third structure 701 of FIG. 7. The removals of the second hard mask layer 712 and the removals of the exposed portions of the sacrificial layer 610 and the first gate dielectric 540 can be executed as a stripping and/or ashing of these materials and exposes the third section 511₃ of the STI 511. In the embodiments of FIG. 8B, residuals of the sacrificial layer 610 remain on the remainder of the first gate dielectric 540 and surround the semiconductor channels 521 and the high-k dielectric layer 522.

The following description will relate to the embodiments of FIG. 8A. This is being done for purposes of clarity and brevity and is not intended to limit the disclosure or the claims in any way.

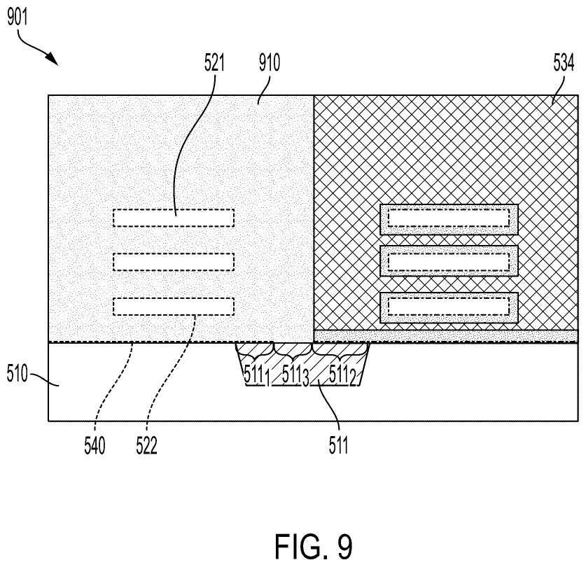

As shown in FIG. 9, a fifth structure 901 of a semiconductor device being fabricated is provided following nFET WFM 910 (i.e., the nFET WFM 123 of FIG. 1) deposition executed with respect to the fourth structure 801 of FIG. 8. The nFET WFM 910 surrounds the semiconductor channels 521 and the high-k dielectric layer 522 and is disposed over the first gate dielectric 540. In addition, the nFET WFM 910 contacts the third section 511₃ of the STI 511 to thus provide for a path for oxygen vacancy which will allow for a reduction of the metal gate boundary effect of the semiconductor device being fabricated.

Once the nFET WFM 910 is deposited, the nFET WFM 910 is planarized to expose the reliability polysilicon 534. This allows the reliability polysilicon 534 to be removed and replaced with the pFET WFM 134 (see FIG. 1), which is planarized to arrive at the semiconductor device 101 of FIG. 1.

Various embodiments are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and this disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments will now be provided. Although specific fabrication operations used in implementing one or more embodiments can be individually known, the described combination of operations and/or resulting structures are unique. Thus, the unique combination of the operations described in connection with the fabrication of a semiconductor device according to this disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device, comprising:
a substrate;
first and second field effect transistors (FETs) of opposite polarity, the first FET being disposed on a first side of the substrate and comprising first work function metal (WFM) and the second FET being disposed on a second side of the substrate and comprising second WFM;
a first gate dielectric disposed over at least the first side of the substrate; and
a second gate dielectric disconnected from the first gate dielectric and disposed over at least the second side of the substrate,
the second WFM being aligned with the second gate dielectric and the first WFM extending beyond the first gate dielectric.

2. The semiconductor device according to claim 1, wherein the first WFM contacts the second WFM in a plane aligned with an edge of the second gate dielectric.

3. The semiconductor device according to claim 1, wherein the first and second FETs are nanosheet transistors.

4. The semiconductor device according to claim 1, wherein the first and second FETs are finFETs.

5. The semiconductor device according to claim 1, wherein the first and second FETs are vertical tunnel FETs.

6. The semiconductor device according to claim 1, wherein the first and second gate dielectrics are different materials.

7. The semiconductor device according to claim 1, wherein the first gate dielectric comprises one of an interfacial layer and a high-k dielectric and the second gate dielectric comprises an interfacial layer and a high-k dielectric.

8. A semiconductor device, comprising:
a substrate comprising a shallow trench isolation (STI);
an n-doped field effect transistor (nFET) disposed on a first side of the substrate;
a p-doped field effect transistor (pFET) disposed on a second side of the substrate;
a first gate dielectric disposed over the first side of the substrate and a first section of the STI; and
a second gate dielectric disconnected from the first gate dielectric and disposed over the second side of the substrate and a second section of the STI,
the pFET comprising pFET work function metal (WFM) aligned with the second gate dielectric, and
the nFET comprising nFET WFM extending beyond the first gate dielectric to contact a third section of the STI, which is interposed between the first and second sections of the STI.

9. The semiconductor device according to claim 8, wherein the nFET WFM contacts the pFET WFM in a plane aligned with an edge of the second gate dielectric.

10. The semiconductor device according to claim 8, wherein the nFET and the pFET are nanosheet transistors.

11. The semiconductor device according to claim 8, wherein the nFET and the pFET are finFETs.

12. The semiconductor device according to claim 8, wherein the nFET and the pFET are vertical tunnel FETs.

13. The semiconductor device according to claim 8, wherein the first and second gate dielectrics are different materials.

14. The semiconductor device according to claim 8, wherein the first gate dielectric comprises one of an interfacial layer and a high-k dielectric and the second gate dielectric comprises an interfacial layer and a high-k dielectric.

15. A semiconductor device fabrication method with first and second field effect transistor (FET) structures being formed on a substrate comprising a shallow trench isolation (STI) and the second FET structure comprising second gate dielectric and polysilicon, the semiconductor device fabrication method comprising:
disposing first gate dielectric over the substrate and exposed portions of the STI, the second gate dielectric and the polysilicon;
depositing a sacrificial layer over the first gate dielectric;
masking a portion of the sacrificial layer;
removing unmasked portions of the sacrificial layer and the first gate dielectric;
removing at least a portion of a remainder of the sacrificial layer;
depositing a first work function metal (WFM) onto a remainder of the first gate dielectric and an exposed section of the STI; and
replacing the polysilicon with a second WFM.

16. The semiconductor device fabrication method according to claim 15, wherein the first gate dielectric comprises one of an interfacial layer and a high-k dielectric and the second gate dielectric comprises an interfacial layer and a high-k dielectric.

17. The semiconductor device fabrication method according to claim 15, wherein the first WFM contacts the exposed section of the STI and the second WFM in a plane aligned with an edge of the second gate dielectric.

18. The semiconductor device fabrication method according to claim 15, wherein the first and second FET structures comprise at least one of nanosheet FETs, finFETs and vertical tunnel FETs.

19. The semiconductor device fabrication method according to claim 15, wherein the masking of the portion of the sacrificial layer comprises masking the portion of the sacrificial layer and the first FET structure.

20. The semiconductor device fabrication method according to claim 15, wherein the removing of the at least the portion of the remainder of the sacrificial layer comprises removing an entirety of the remainder of the sacrificial layer.
